(19) United States
(12) Patent Application Publication
(10) Pub. No.: US 2010/0214525 A1
(43) Pub. Date: Aug. 26, 2010

(54) IMAGE DISPLAY DEVICE

(75) Inventors: Shinya Yamaguchi, Mitaka (JP); Mutsuko Hatano, Kokubunji (JP); Takashi Hattori, Musashimurayama (JP); Naoya Okada, Kokubunji (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(73) Assignee: Hitachi Displays, Ltd.

(21) Appl. No.: 12/702,881

(22) Filed: Feb. 9, 2010

(30) Foreign Application Priority Data
Feb. 26, 2009 (JP) 2009-043825

(51) Int. Cl. G02F 1/1333; H01J 1/62; H05K 1/00

(52) U.S. Cl. 349/160; 313/504; 174/254

(57) ABSTRACT

Provided is an image display device, including: a first flexible substrate; and a circuit-forming layer constituting an image display area, the circuit-forming layer being made to adhere to one of surfaces of the first flexible substrate, in which, when the first flexible substrate has a thickness of t2, the circuit-forming layer has a thickness of t1 satisfying the following Equation (1):

t1≧3/40×(t2-23) (1).

### CROSS-REFERENCE TO RELATED APPLICATION

The present application claims priority from Japanese application JP2009-043825 filed on Feb. 26, 2009, the content of which is hereby incorporated by reference into this application.

### BACKGROUND OF THE INVENTION

1. Field of the Invention

The present invention relates to an image display device, in particular, an image display device including a flexible substrate made of a resin or the like.

2. Description of the Related Art

A liquid crystal display device (panel), which is one of image display devices, includes as an envelope a pair of substrates. The pair of substrates are provided so as to be opposed to each other with liquid crystal interposed therebetween. On a surface of each of the pair of substrates, which is on a liquid crystal side, an image display area including a plurality of pixels arranged in matrix is formed.

In a liquid crystal display device driven by active matrix, at least a thin film transistor and a pixel electrode are formed in each of the pixels of the image display area of one of the substrates. The thin film transistor is turned ON by a scanning signal from a gate bus line. A video signal from a drain bus line is supplied through the thus turned-ON thin film transistor to the pixel electrode.

The gate bus line, the thin film transistor, the drain bus line, the image electrode, and the like are formed of a laminate formed by depositing a conductor layer (such as a metal layer) which is patterned by so-called photolithography, an insulator layer (such as a silicon oxide film or a silicon nitride film), a semiconductor layer (such as a silicon layer), and the like in a predetermined order (the laminate is sometimes referred to as a circuit-forming layer in this specification), on the surface of the one of the substrates.

Moreover, in recent years, a liquid crystal display device including flexible substrates made of a resin or the like in place of conventional glass substrates has come to be known. The liquid crystal display device including the flexible substrates in place of the glass substrates is lightweight and is hardly damaged. Moreover, a display surface of the liquid crystal display device described above can be bent for use as needed.

The circuit-forming layer of the liquid crystal display device as described above requires a high temperature for the formation thereof, and hence the liquid crystal display device including the flexible substrates is generally formed in the following process. First, the circuit-forming layer is formed on a glass substrate. After that, the circuit-forming layer is, for example, peeled off from the glass substrate. Then, the circuit-forming layer is made to adhere to a separately prepared flexible substrate through an intermediation of an adhesive layer.

The image display device having the structure described above is disclosed in, for example, JP 2007-310417 A and JP 2008-026910 A.

### SUMMARY OF THE INVENTION

In the image display devices including the aforementioned liquid crystal display device, however, the circuit-forming layer mainly includes the silicon oxide film or the silicon nitride film as a principal material which is formed over almost the entire area of the image display area. Therefore, the circuit-forming layer is made of a hard material having an elastic constant as large as that of glass. On the other hand, the flexible substrates are made of, for example, the resin which is a soft material.

Thus, a stress is likely to be generated in each of the flexible substrate and the circuit-forming layer which adhere to each other through the adhesive layer due to, for example, a difference in thermal expansion coefficient or bend. When the stress exceeds a breaking stress of the circuit-forming layer, cracks are sometimes generated in the circuit-forming layer.

It is an object of the present invention to provide an image display device including a circuit-forming layer in which cracks are hardly generated.

In the image display device according to the present invention, a thickness of the circuit-forming layer is set to a predetermined value or larger according to a thickness of a flexible substrate to which the circuit-forming layer is made to adhere, thereby reducing the generation of the cracks in the circuit-forming layer.

A structure of the present invention can be, for example, as follows.

(1) An image display device according to the present invention includes: a first flexible substrate; and a circuit-forming layer constituting an image display area, the circuit-forming layer being made to adhere to one of surfaces of the first flexible substrate, in which, when the first flexible substrate has a thickness of t2, the circuit-forming layer has a thickness of t1 satisfying the following Equation (1):

t1≧3/40×(t2-23) (1).

(2) In the image display device of the present invention according to Item (1), the circuit-forming layer includes a plurality of pixels arranged in matrix in plan view, and each of the pixels includes: at least a thin film transistor turned ON by a scanning signal from a gate bus line; and an electrode to which a video signal from a drain bus line is supplied through the turned-ON thin film transistor.

(3) In the image display device of the present invention according to Item (2), the circuit-forming layer is formed of a laminate obtained by depositing a conductor layer patterned by photolithography, an insulator layer, and a semiconductor layer in a predetermined order.

(4) In the image display device of the present invention according to Item (3), the insulator layer includes at least any one of a silicon oxide film and a silicon nitride film.

(5) In the image display device of the present invention according to Item (1), the first flexible substrate is made of polyimide.

(6) In the image display device of the present invention according to Item (1), the first flexible substrate is made of polystyrene.

(7) The image display device of the present invention according to Item (1) further includes a second flexible substrate provided on the surface of the first flexible substrate, on which the circuit-forming layer is formed, so as to be opposed thereto with liquid crystal interposed between the first flexible substrate and the second flexible substrate, to thereby constitute a liquid crystal display device.

(8) In the image display device of the present invention according to Item (1), further comprising a second flexible substrate serving as a sealing substrate is provided on the surface of the first flexible substrate, on which the circuit-forming layer is formed, to thereby constitute an organic EL display device.

The aforementioned structure is merely an example, and the present invention can appropriately be changed without departing from its technical idea. Examples of the structure of the present invention other than those described above become apparent from the description throughout the specification of the present application or the accompanying drawings.

According to the aforementioned image display device, the generation of the cracks in the circuit-forming layer can be reduced.

The other effects of the present invention become apparent from the description throughout the specification.

### BRIEF DESCRIPTION OF THE DRAWINGS

In the accompanying drawings:

FIG. 1 is a view illustrating a schematic structure of a first embodiment of an image display device according to the present invention;

FIG. 2 is an equivalent circuit diagram of an image display area formed by a circuit-forming layer of the image display device according to the present invention;

FIG. 3 is a view illustrating the image display device according to the present invention in an ideally separated manner in view of stress control such as an elastic constant and a thermal expansion coefficient of each of materials;

FIG. 4 is a table showing principal materials used for fabrication of the image display device of the present invention;

FIG. 5A is a view illustrating stresses due to thermal expansion, which are generated in a liquid crystal display device;

FIG. 5B is another view illustrating the stresses due to thermal expansion, which are generated in the liquid crystal display device;

FIG. 6A is a view illustrating the stresses generated by bending the liquid crystal display device;

FIG. 6B is another view illustrating the stresses generated by bending the liquid crystal display device;

FIG. 7 is an explanatory view showing an example of a calculation of the stress generated in a laminate film of a first thin film and a second thin film which are made to adhere to each other by a computation;

FIG. 8 is a stress graph obtained by an equation given according to FIG. 7;

FIG. 9 is a graph obtained by plotting the stress graph shown in FIG. 7 in a contour plan form;

FIG. 10 is a view illustrating a cellular phone;

FIG. 11 is a view illustrating a portable game machine;

FIG. 12 is a view illustrating an electronic book; and

FIG. 13 is a view illustrating a pair of electronic goggles.

### DETAILED DESCRIPTION OF THE INVENTION

Each of exemplary embodiments of the present invention is described referring to the accompanying drawings. The same or similar components are denoted by the same reference symbols in each of the drawings and each of the embodiments, and the overlapping description thereof is herein omitted.

### Embodiment 1

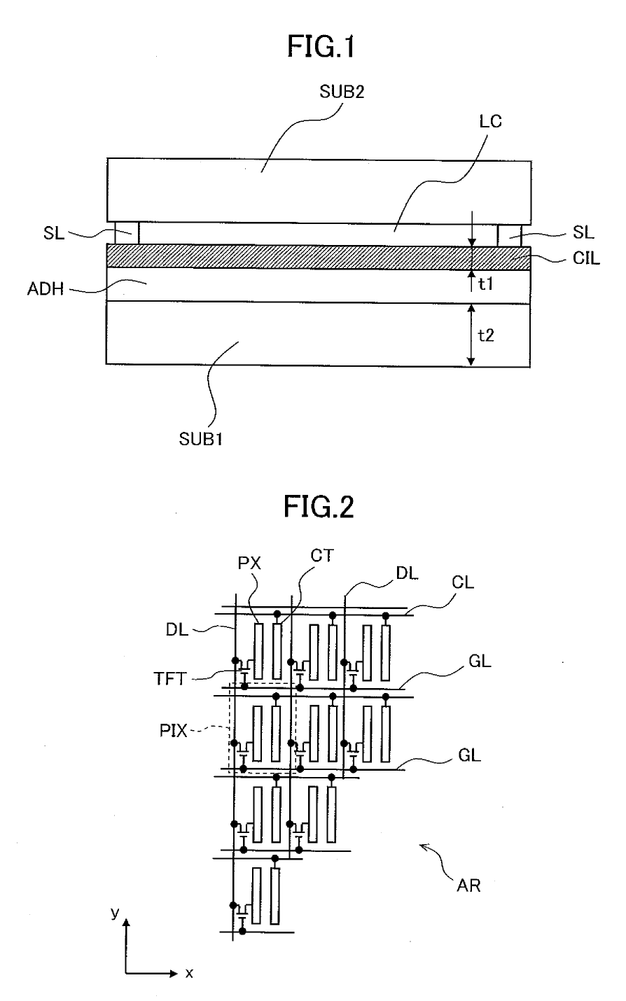

FIG. 1 is a view illustrating a schematic structure of a first embodiment of an image display device of the present invention. The image display device illustrated in FIG. 1 is, for example, a liquid crystal display device (panel). A pair of substrates constituting an envelope of the image display device are flexible substrates made of a resin or the like.

As illustrated in FIG. 1, a first flexible substrate SUB1 is provided. On a surface of the first flexible substrate SUB1 on a liquid crystal LC side, a circuit-forming layer CIL is formed through an intermediation of an adhesive material ADH. The circuit-forming layer CIL constitutes an image display area AR in plan view.

The circuit-forming layer CIL is formed by depositing a patterned conductor layer (metal layer), an insulator layer (made of silicon oxide, silicon nitride, or the like), a semiconductor layer (made of silicon or the like) and the like in a predetermined order. A plurality of pixels are arranged in matrix on a surface of the circuit-forming layer CIL on the liquid crystal LC side. FIG. 2 illustrates an equivalent circuit of the image display area AR formed by the circuit-forming layer CIL. As illustrated in FIG. 2, each pixel region (surrounded by a dot line and denoted by PIX in FIG. 2) in this embodiment is a rectangular region surrounded by a pair of gate bus lines GL arranged in parallel in a y-direction of FIG. 2, each extending in an x-direction of FIG. 2, and a pair of drain bus lines DL arranged in parallel in the x-direction of FIG. 2, each extending in the y-direction of FIG. 2. A thin film transistor TFT, a pixel electrode PX, and a counter electrode CT are provided in the pixel region. The thin film transistor TFT is turned ON by supplying a scanning signal from one of the gate bus lines GL. Through the thus turned-ON thin film transistor TFT, a video signal from one of the drain bus lines DL is supplied to the pixel electrode PX. With the pixel electrode PX, the counter electrode CT generates an electric field in the liquid crystal LC. A reference signal for the video signal is supplied through a common bus line CL to the counter electrode CT. The liquid crystal display device having the pixels as described above is called an in-plane switching (IPS) liquid crystal display device. However, the present invention is applicable not only to the liquid crystal display device having the IPS structure but also to a liquid crystal display device having a structure called twisted nematic (TN), super twisted nematic (STN), or vertical alignment(VA).

The thus formed circuit-forming layer CIL requires a high temperature for the formation thereof, and hence the circuit-forming layer CIL is first formed on an upper surface of a glass substrate or the like. Then, the circuit-forming layer CIL is peeled off from the glass substrate and is then transferred onto the first flexible substrate SUB1 through an intermediation of the adhesive material ADH.

The first flexible substrate SUB1, on which the circuit-forming layer CIL is formed in the aforementioned manner, is made to adhere to a second flexible substrate. SUB2 through an intermediation of a sealing material SL. The second flexible substrate SUB2 is made of, for example, the same material as the first flexible substrate SUB1, and has substantially the same thickness as that of the first flexible substrate SUB1.

The sealing material SL is formed so as to surround the image display area AR including the plurality of pixels formed on the circuit-forming layer CIL. The liquid crystal LC is sealed in a space between the first flexible substrate SUB1 and the second flexible substrate SUB2, which is surrounded by the sealing material SL. Although not shown in the drawings, a black matrix, a color filter, or the like is formed on a surface of the second flexible substrate SUB2 on the liquid crystal LC side.

In this case, in FIG. 1, when a thickness of the first flexible substrate SUB1 is t2, a thickness t1 of the circuit-forming layer CIL satisfies Equation (1):

t1≧3/40·(t2-23) (1).

Satisfying the Equation (1), generation of cracks in the circuit-forming layer CIL is reduced.

Hereinafter, the reason thereof is described in detail below.

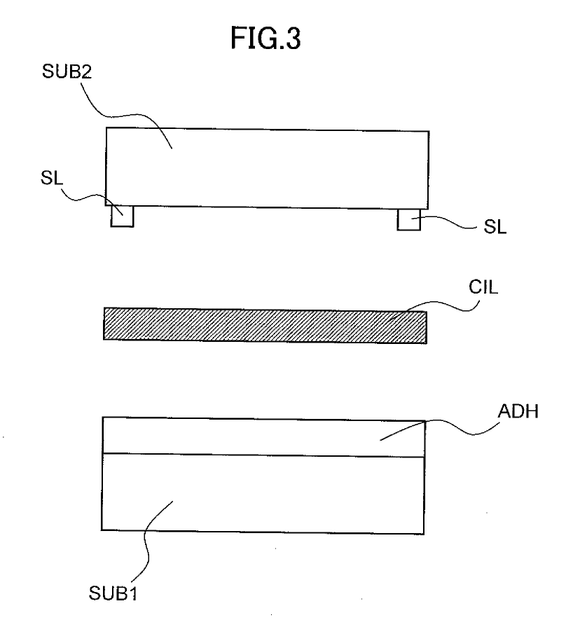

FIG. 3 is a view illustrating the liquid crystal display device configured as described above in an ideally separated manner in view of stress control such as an elastic constant and a thermal expansion coefficient of a material. As illustrated in FIG. 3, the liquid crystal display device is separated into three, that is, for example, the first flexible substrate SUB1 including the adhesive material ADH, the circuit-forming layer CIL, and the second flexible substrate SUB2 including the sealing material SL. The first flexible substrate SUB1 including the adhesive material ADH is mainly made of plastic, a resin, or the like. The circuit-forming layer CIL is mainly made of silicon, silicon oxide, glass, or the like. The second flexible substrate SUB2 including the sealing material SL is mainly made of plastic, the resin, or the like. The three structures obtained by the separation in an ideal manner are sometimes referred to as “three basic structures” in the following description.

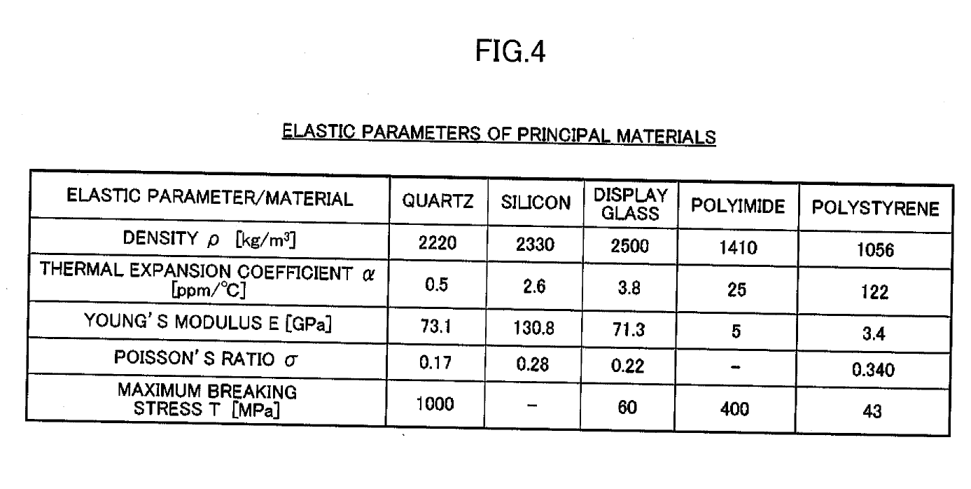

FIG. 4 is a table showing principal materials (quartz, silicon, glass, polyimide, and polystyrene) used for the fabrication of the liquid crystal display device as well as a density ρ (kg/m³) , a thermal expansion coefficient α (ppm/° C.) , a Young's modulus E (GPa) , Poisson's ratio σ, a maximum breaking stress T (MPa) of each of the materials. The principal materials are roughly classified into two material groups, that is, a hard-material group (with a small thermal expansion coefficient and a large Young's modulus) and a soft-material group (with a large thermal expansion coefficient and a small Young's modulus). The former group includes quartz, silicon, and glass, whereas the latter group includes polyimide and polystyrene.

According to the aforementioned classification, the first flexible substrate SUB1 including the adhesive material ADH and the second flexible substrate SUB2 including the sealing material SL illustrated is FIG. 3 are included in the soft-material group, whereas the circuit-forming layer CIL is included in the hard-material group. Therefore, the liquid crystal display device has a sandwich structure including the material of the hard-material group vertically interposed between the materials of the soft-material group.

Hereinafter, it is supposed that the liquid crystal display device has the sandwich structure (the three basic structures) including the material of the hard-material group vertically interposed between the materials of the soft-material group as described above. A stress exerted on each of the materials of the material groups is examined.

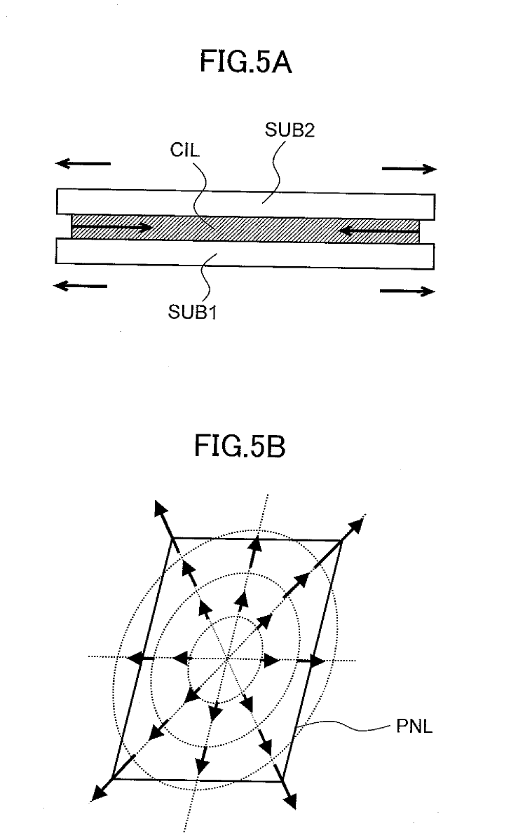

FIG. 5A is a sectional view illustrating stresses generated due to thermal expansion occurring in the liquid crystal display device. When heat is applied in the process of fabricating the liquid crystal display device, stresses due to differences in expansion/contraction are generated in the three basic structures respectively having different thermal expansion coefficients. Taking a temperature elevating process as an example, the thermal expansion of each of the first flexible substrate SUB1 and the second flexible substrate SUB2 is relatively larger than that of the circuit-forming layer CIL. Therefore, an outward tensile stress for outwardly pulling the circuit-forming layer CIL (indicated by arrows in FIG. 5A) by each of the first flexible substrate SUB1 and the second flexible substrate SUB2 is generated. On the other hand, the same degree of stress but acting in the opposite direction (indicated by arrows in FIG. 5A) is generated in the circuit-forming layer CIL. As a result, the stress generated in the circuit-forming layer CIL is balanced with the stresses generated in the first flexible substrate SUB1 and the second flexible substrate SUB2 (indicated by the arrows in FIG. 5A). Then, paying notice to the circuit-forming layer CTL, the outward tensile stress (indicated by the arrows in FIG. 5A) concentrically increases from a center of the panel, as illustrated in a plan view of FIG. 5B. The degree of stress (indicated by arrows in FIG. 5B) increases in proportion to a distance from the center of the panel, and hence the stress becomes the largest at four corners of the panel. When a value of the stress at the corners of the panel (indicated by the arrows in FIG. 5B) corresponds to the maximum breaking stress, the cracks occur in the circuit-forming layer CIL.

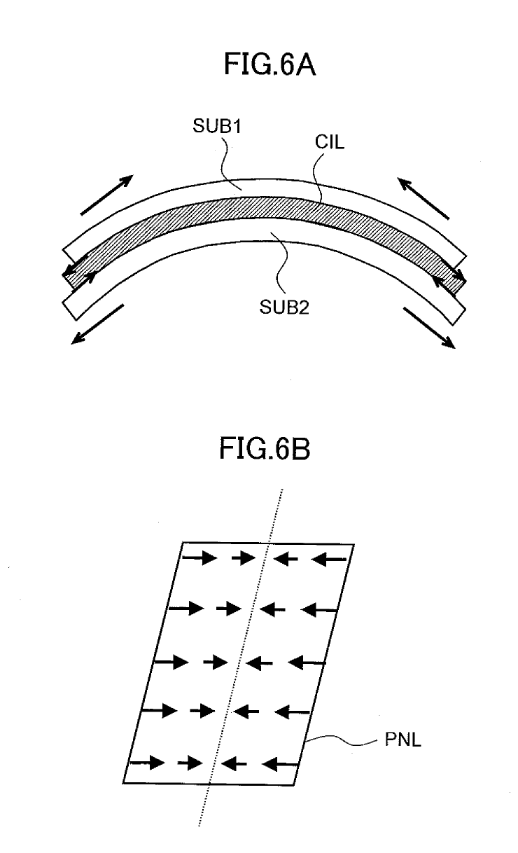

FIG. 6A is a sectional view illustrating the stresses generated by bending the liquid crystal display device. When the liquid crystal display device is bent, for example, as illustrated in FIG. 6A, the stresses (indicated by arrows in FIG. 6A) are generated due to differences in expansion/contraction between the layers of the three basic structures. In this case, the direction of the stress generated in the first flexible substrate SUB1 is opposite to that of the stress generated in the second flexible substrate SUB2 (indicated by arrows in FIG. 6A). Therefore, onto an upper surface of the circuit-forming layer CIL, the outward tensile stress (indicated by arrows in FIG. 6A) is applied from the second flexible substrate SUB2. On the other hand, onto a lower surface of the circuit-forming layer CIL, an inward compressive stress (indicated by arrows in FIG. 6A) is applied from the first flexible substrate SUB1. Then, paying notice to the circuit-forming layer, the stress generated in the circuit-forming layer CIL (indicated by arrows in FIG. 6B) is distributed in a symmetric manner with respect to a principal axis of the bend, as illustrated in a plan view of FIG. 6B, and increases according to a distance from the principal axis. The stress (indicated by the arrows in FIG. 6B) becomes the largest on right and left ends of the panel. When a value of the stress on the right and left ends of the panel (indicated by the arrows in FIG. 6B) corresponds to the maximum breaking stress, the cracks are generated in the circuit-forming layer CIL.

As described above, the aforementioned stresses due to thermal expansion and bend are generated in the liquid crystal display device. The stresses are now calculated by a computation.

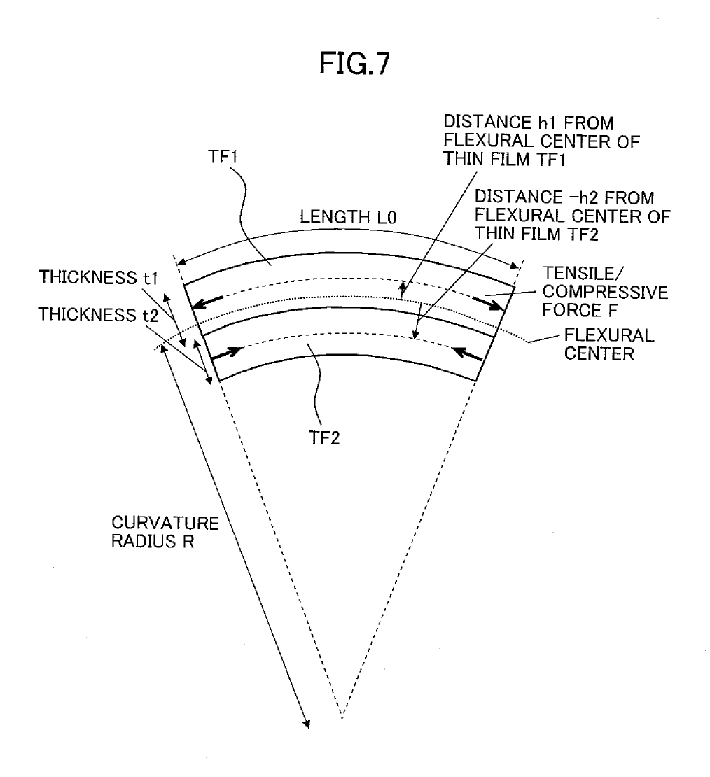

FIG. 7 illustrates a laminate film of a first thin film TF1 and a second thin film TF2 which are bonded to each other. The first thin film TF1 conceptually corresponds to the circuit-forming layer which has the elastic constant as large as that of glass. The second thin film TF2 conceptually corresponds to the flexible substrate which has the elastic constant as small as that of polystyrene.

A temperature is changed from an initial temperature T0 to a temperature T. At this time, as illustrated in FIG. 7, the laminate film is bent so as to have a curvature radius of R. In this case, for the first thin film TF1, an initial length is L0, a length after bend is L1, a thermal expansion coefficient is α1, a Young's modulus is E1, a distance from a flexural center is h1, a film thickness is t1, and a tensile/compressive force exerted by the second thin film TF2 is F. Then, a relation expressed by the following Equation (2) is established.

$$\begin{matrix}[ Equation 2 ] & \\ {L}_{1} = {L}_{0} + {L}_{0} {α}_{1} ( T - {T}_{0} ) + {L}_{0} \frac{{h}_{1}}{R} + {L}_{0} \frac{F}{{t}_{1} {E}_{1}} & ( 2 )\end{matrix}$$

In Equation (2), a second term of a right-hand side expresses expansion/contraction due to the change in temperature, a third term expresses expansion/contraction due to the bend, and a forth term expresses expansion/contraction due to the tensile/compressive force applied from the second thin film TF2.

Further, for the second thin film TF2, an initial length is L0, a length after bend is L2, a thermal expansion coefficient is α2, a Young's modulus is E2, a distance from a flexural center is h2, a film thickness is t2, and a tensile/compressive force exerted by the first thin film TF1 is F. Then, a relation expressed by the following Equation (3) is established.

$$\begin{matrix}[ Equation 3 ] & \\ {L}_{2} = {L}_{0} + {L}_{0} {α}_{2} ( T - {T}_{0} ) + {L}_{0} \frac{{h}_{2}}{R} - {L}_{0} \frac{F}{{t}_{2} {E}_{2}} & ( 3 )\end{matrix}$$

Even in Equation (3), a second term of a right-hand side expresses expansion/contraction due to the change in temperature, a third term expresses expansion/contraction due to the bend, and a forth term expresses expansion/contraction due to the tensile/compressive force applied from the first thin film TF1. In comparison with Equation (2) , a sign of the tensile/compressive force applied from the first thin film TF1 is reversed in the fourth term of the right-hand side of Equation (3).

Assuming that the first thin film TF1 and the second thin film TF2 are balanced with each other with the same tensile/compressive force F and are held in close contact with each other without misalignment therebetween in this case, the following Equation (4) is established.

[Equation 4]

L₁=L₂ (4)

Then, the tensile/compressive force F is calculated from the aforementioned Equations (2) , (3) , and (4) to obtain the following Equation (5).

$$\begin{matrix}[ Equation 5 ] & \\ F = \frac{{t}_{1} {t}_{2} {E}_{1} {E}_{2}}{{t}_{1} {E}_{1} + {t}_{2} {E}_{2}} ( ( {α}_{2} - {α}_{1} ) ( T - {T}_{0} ) + \frac{{h}_{2} - {h}_{1}}{R} ) & ( 5 )\end{matrix}$$

An internal stress p1 generated in the first thin film TF1 is obtained by dividing the tensile/compressive force F expressed by the aforementioned Equation (5) by the film thickness ti. Then, when the internal stress p1 is smaller than the maximum breaking stress W1 of the first thin film TF1, the cracks can be prevented from being generated in the thin film TF1. Specifically, by limiting the range of the physical parameters of the right-hand side of the following Equation (6), the cracks can be prevented from being generated in the first thin film TF1.

$$\begin{matrix}[ Equation 6 ] & \\ {W}_{1} > {p}_{1} = \frac{{t}_{2} {E}_{1} {E}_{2}}{{t}_{1} {E}_{1} + {t}_{2} {E}_{2}} ( ( {α}_{2} - {α}_{1} ) ( T - {T}_{0} ) + \frac{{h}_{2} - {h}_{1}}{R} ) & ( 6 )\end{matrix}$$

The case where 300° C. corresponding to the highest temperature used in the process is used as a change in temperature (T-T0) and 150 mm is used as the curvature radius R of the bending is supposed. Even if the distance from the flexural center (h2-h1) corresponding to the thickness of the flexible substrate is as large as about 100 μm, it is understood that a value of a second term of a right-hand side of Equation (6) is one or two orders of magnitude less than a value of a first term of the right-hand side of Equation (6). Specifically, it is the thermal expansion component in the first term of the right-hand side of Equation (6) that mainly contributes to the internal stress p1, and the difference in distance from the flexural center does not affect much the internal stress p1.

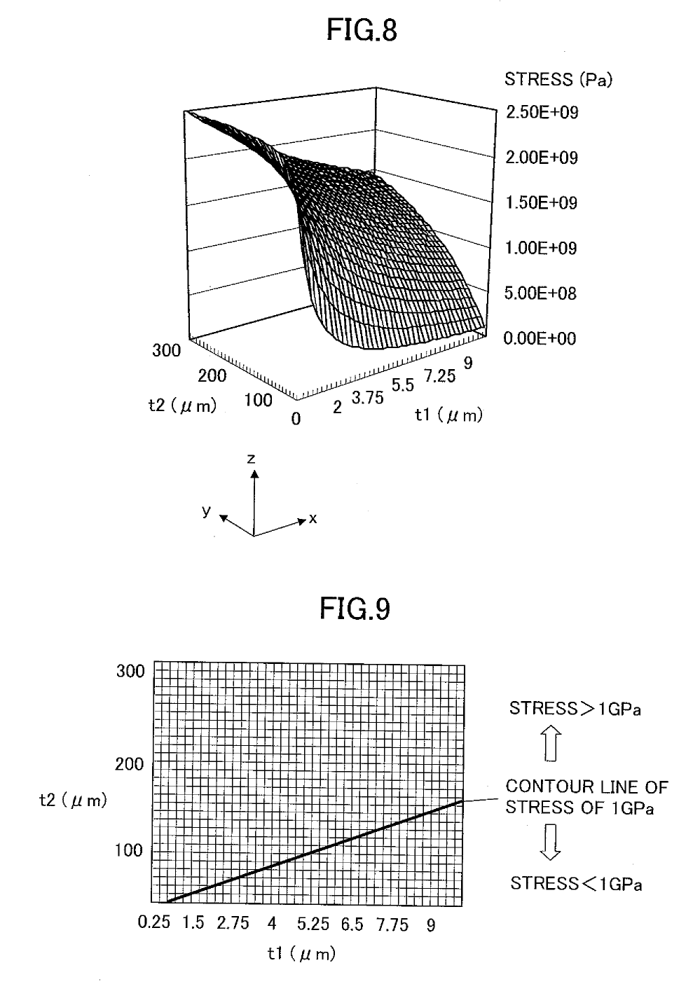

FIG. 8 is a stress graph obtained by Equation (6) described above. In this case, as the values of the Young's moduli E1 and E2, the values shown in FIG. 4 are used. In FIG. 8, the thickness t1 (μm) of the circuit-forming layer is indicated in an x-direction of FIG. 8, the thickness t2 (μm) of the flexible substrate is indicated in a y-direction of FIG. 8, and the stress (Pa) is indicated in a z-direction of FIG. 8. As is made apparent from FIG. 8, the stress slowly reduces as the thickness t1 of the flexible substrate increases. On the other hand, the stress sharply increases as the thickness t2 of the circuit-forming layer CIL increases. From this fact, it is found that the thickness t1 of the circuit-forming layer CIL may be set large and the thickness t2 of the flexible substrate may be set small for reducing the stress.

FIG. 9 is a graph obtained by plotting the stress graph of FIG. 8 in a contour plan form. In FIG. 9, when a contour line of the stress of 1GPa is used as a reference, a region above the contour line in FIG. 9 corresponds to the stress larger than 1 GPa, whereas a region therebelow in FIG. 9 corresponds to the stress less than 1 GPa. From the maximum breaking stresses of Table 1, quartz has the maximum breaking stress of just about 1 GPa. The circuit-forming layer is mainly formed of a laminated body including the silicon oxide film or the silicon nitride film. Therefore, it is supposed that the circuit-forming layer has the maximum braking stress between that of glass and that of quartz. However, the maximum breaking stress of the circuit-forming layer can be defined as being approximately equal to that of quartz (1 GPa) without any substantial problems.

Based on the aforementioned fact, according to FIG. 9, when the thickness t2 of the flexible substrate is set to, for example, 100 μm, the cracks can be prevented by setting the thickness t1 of the circuit-forming layer to about 6 μm or larger. Moreover, when the thickness t2 of the flexible substrate is set to, for example, 50 μm, the cracks can be prevented by setting the thickness t1 of the circuit-forming layer to about 3 μm or larger. Specifically, the contour line of the stress of 1 GPa shown in FIG. 9 can be expressed by the following Equation (7).

t1=3/40×(t2-23) (7).

When the thickness of the first flexible substrate SUB1 is t2, the generation of the cracks in the circuit-forming layer CIL can be reduced by setting the thickness t1 of the circuit-forming layer CIL so as to satisfy the following Equation (1).

t1≧3/40×(t2-23) (1).

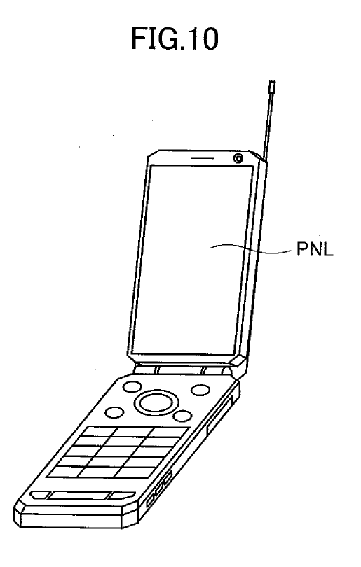

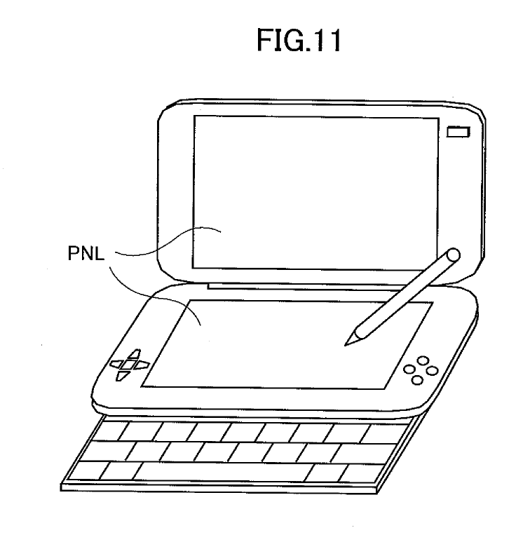

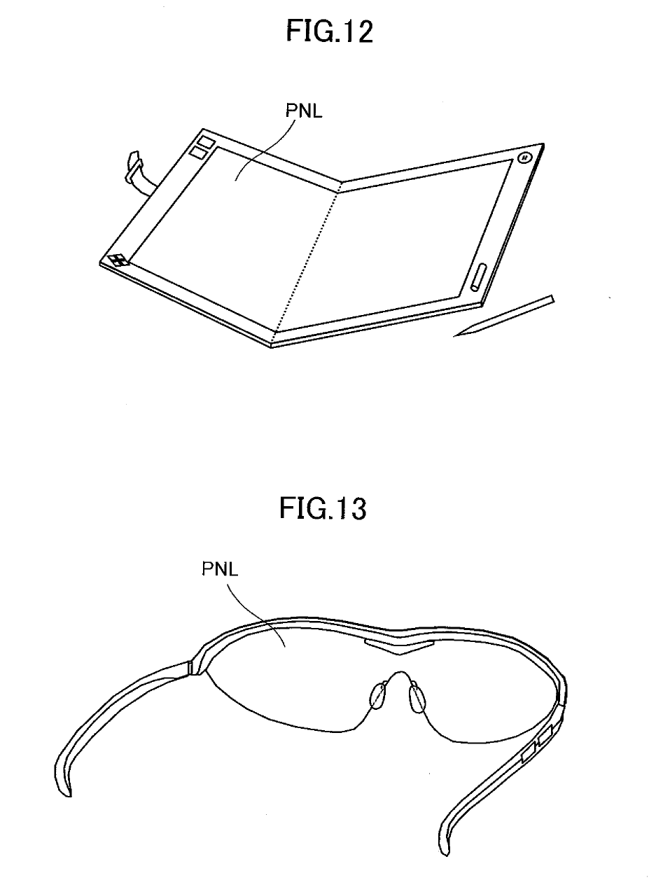

Each of FIGS. 10 to 13 illustrates an example of an electronic device to which the present invention is applied. FIG. 10 illustrates a cellular phone. The cellular phone includes a liquid crystal display panel PNL having the flexible substrate as the substrate, to which the present invention is applied. FIG. 11 illustrates a portable game machine including the liquid crystal display panel PNL having the flexible substrate as the substrate, to which the present invention is applied. FIG. 12 illustrates an electronic book including the liquid crystal display panel PNL having the flexible substrate as the substrate, to which the present invention is applied. FIG. 13 illustrates a pair of electronic goggles including the liquid crystal display panel PNL having the flexible substrate as the substrate, to which the present invention is applied.

### Embodiment 2

In the first embodiment, the circuit-forming layer CIL is first formed on the upper surface of a glass substrate, is then peeled off from the glass substrate, and is finally transferred onto the flexible substrate through an intermediation of the adhesive material. However, the formation of the circuit-forming layer is not limited thereto. The circuit-forming layer may also be formed in the following manner. After the circuit-forming layer is formed on the upper surface of the glass substrate or the like, a thickness of the glass substrate is reduced by etching. The circuit-forming layer CIL including the glass substrate having the thus reduced thickness is made to adhere to the flexible substrate. In this case, the thickness of the circuit-forming layer is considered to include the thickness of the glass substrate.

### Embodiment 3

The liquid crystal display device has been described as an example of the image display device in the first and second embodiments . However, the application of the present invention is not limited to the liquid crystal display device. The present invention is also applicable to, for example, an organic EL display device because the organic EL display device also includes the circuit-forming layer which can have the structure in which the circuit-forming layer is made to adhere to the flexible substrates through an intermediation of the adhesive material. The circuit-forming layer of the organic EL display device includes an anode (a cathode) in the pixel region, which corresponds to the pixel electrode of the liquid crystal display device, a fluorescent layer formed on an upper surface of the anode (the cathode), and a cathode (an anode) formed thereon. By supplying a current to the fluorescent layer, the fluorescent layer emits light.

Moreover, on a surface of the flexible substrate (the first flexible substrate) on which the circuit-forming layer is formed, a flexible substrate (a second flexible substrate) serving as a sealing substrate is provided.

Although the present invention has been described with the embodiments, the structures described in the above-mentioned embodiments are merely examples. The present invention may be changed or modified without departing from its technical idea. The structures described in the embodiments may be used in combination as long as they do not conflict with each other.

What is claimed is:

1. An image display device, comprising:
a first flexible substrate; and
a circuit-forming layer constituting an image display area, the circuit-forming layer being made to adhere to one of surfaces of the first flexible substrate,
wherein, when the first flexible substrate has a thickness of t2, the circuit-forming layer has a thickness of t1 satisfying the following Equation (1):
t1≧3/40×(t2-23) (1).

2. The image display device according to claim 1, wherein:
the circuit-forming layer includes a plurality of pixels arranged in matrix in plan view; and
each of the pixels includes:
at least a thin film transistor turned ON by a scanning signal from a gate bus line; and
an electrode to which a video signal from a drain bus line is supplied through the turned-ON thin film transistor.

3. The image display device according to claim 2, wherein the circuit-forming layer is formed of a laminate obtained by depositing a conductor layer patterned by photolithography, an insulator layer, and a semiconductor layer in a predetermined order.

4. The image display device according to claim 3, wherein the insulator layer includes at least any one of a silicon oxide film and a silicon nitride film.

5. The image display device according to claim 1, wherein the first flexible substrate is made of polyimide.

6. The image display device according to claim 1, wherein the first flexible substrate is made of polystyrene.

7. The image display device according to claim 1, further comprising a second flexible substrate provided on the surface of the first flexible substrate, on which the circuit-forming layer is formed, so as to be opposed thereto,
wherein the first flexible substrate and the second flexible substrate interpose liquid crystal therebetween, to thereby constitute a liquid crystal display device.

8. The image display device according to claim 1, further comprising a second flexible substrate serving as a sealing substrate is provided on the surface of the first flexible substrate, on which the circuit-forming layer is formed, to thereby constitute an organic EL display device.
